(19) United States
(12) Patent Application Publication
(10) Pub. No.: US 2013/0247968 A1
(43) Pub. Date: Sep. 26, 2013

(54) PHOTOELECTRIC DEVICE

(71) Applicants: Sung-Su Kim, Yongin-si (KR); Hyun-Chul Kim, Yongin-si (KR)

(72) Inventors: Sung-Su Kim, Yongin-si (KR); Hyun-Chul Kim, Yongin-si (KR)

(21) Appl. No.: 13/551,561

(22) Filed: Jul. 17, 2012

Related U.S. Application Data
(60) Provisional application No. 61/613,470, filed on Mar. 20, 2012.

(51) Int. Cl. H01L 31/0224; H01L 31/0203; H01L 31/02

(52) U.S. Cl. 136/256; 136/252; 136/259

(57) ABSTRACT

A photoelectric device includes first and second substrates facing each other, a separator between the first and second substrates and having a plurality of openings such that opposite first and second surfaces of the separator are fluidly connected to each other, and first and second electrodes on the first and second surfaces of the separator, respectively, wherein the first and second electrodes are fluidly connected to the openings of the separator.

### CROSS-REFERENCE TO RELATED APPLICATION

This application claims priority to and the benefit of U.S. Provisional Application No. 61/613,470, filed on Mar. 20, 2012, in the USPTO, the disclosure of which is incorporated herein in its entirety by reference.

### BACKGROUND

1. Field

One or more embodiments of the present invention relate to a photoelectric device.

2. Description of Related Art

Photoelectric conversion devices that convert light energy to electric energy, and solar cells using sun light to generate electric energy, have drawn much attention as energy sources that can replace fossil fuel.

Solar cells using various driving principles have been studied, and dye sensitized solar cells, which have a very high photoelectric conversion efficiency when compared to conventional solar cells, are being considered as next-generation solar cells.

The dye sensitized solar cells include a photosensitive dye that receives incident light having one or more wavelengths in the visible spectrum to generate excited electrons from the incident light, a semiconductor material capable of receiving the excited electrons, and an electrolyte capable of reacting with electrons that returns after passing through an external circuit.

### SUMMARY

One or more embodiments of the present invention include a photoelectric device for which materials and manufacturing costs may be reduced, and also, for which loss due to electrical resistance may be reduced.

According to one or more embodiments of the present invention, there is provided a photoelectric device including first and second substrates facing each other, a separator between the first and second substrates and having a plurality of openings such that opposite first and second surfaces of the separator are fluidly connected to each other, and first and second electrodes on the first and second surfaces of the separator, respectively, wherein the first and second electrodes are fluidly connected to the openings of the separator.

The first and second electrodes may each have openings.

The openings of the first and second electrodes may be aligned with the openings of the separator.

The first and second electrodes may each include a metal plate.

The first and second electrodes may each include titanium.

The photoelectric device may further include a light-absorbing layer on the first electrode, and a catalyst layer on the second electrode.

The light-absorbing layer may be on a surface of the first electrode facing the first substrate, and the catalyst layer may be on a surface of the second electrode facing the second substrate.

The first and second electrodes, the light-absorbing layer, and the catalyst layer may each have openings that are fluidly connected to the openings of the separator.

The openings of the separator may have a generally regular pattern.

At least a portion of the separator may be porous.

The photoelectric device may further include an electrolyte between and directly contacting the first and second substrates.

The separator may include an insulating material to electrically insulate the first and second electrodes from each other.

The separator may include at least one of a non-conductive resin material or a porous inorganic material.

The separator may include at least one of polytetrafluoroethylene, a vinyl resin, a silicon (Si) oxide, or a zirconium (Zr) oxide.

The photoelectric device may further include a first spacer between the first substrate and the separator, and a second spacer between the second substrate and the separator.

The photoelectric device may have first and second accommodation spaces that are proximate the first and second spacers, respectively, and that are fluidly connected to each other via the openings in the separator.

The photoelectric device may further include a plurality of first spacers on different portions at a first side of the separator, and a plurality of second spacers on different portions at a second side of the separator.

The photoelectric device may further include a plurality of first and second spacers between the separator and the first and second substrates, respectively, and the separator may be spaced from the first and second substrates.

The first spacer may include a transparent material, and the first substrate may be configured to receive light.

The photoelectric device may further include a sealing member between the first and second substrates and spaced from the separator.

As described above, according to the one or more embodiments of the present invention, a light-absorbing layer is located in front of an electrode structure along a path of light, and thus, an electrode may be formed using a metal having excellent electric conductivity without having to consider light transparency of the electrode structure. Accordingly, compared to a structure in which an electrode is formed of a transparent conducting layer having both optical transparency and electrical conductivity, costs for materials and special processes may be reduced. In addition, by forming an electrode using a metal having higher electric conductivity than a transparent conducting layer, resistance loss in a photocurrent may be reduced and a high photoelectric conversion efficiency may be obtained.

### BRIEF DESCRIPTION OF THE DRAWINGS

FIG. 1 is a disassembled perspective view of a photoelectric device according to an embodiment of the present invention;

FIG. 2 is a cross-sectional view of the photoelectric device of the embodiment shown in FIG. 1 cut along the line II-II;

FIG. 3 is an expanded view of a portion of the photoelectric device of embodiment shown in FIG. 2;

FIG. 4 is a disassembled perspective view of a portion of the photoelectric device of the embodiment shown in FIG. 1;

FIGS. 5A through 5D are views for illustrating formation of openings of a second electrode according to an embodiment of the present invention;

FIGS. 6A and 6B are views for illustrating formation of openings of first and second electrodes and a separator according to an embodiment of the present invention;

FIG. 7 is a plan view of a separator according to another embodiment of the present invention;

FIG. 8 is a cross-sectional view of a photoelectric device according to a comparative example;

FIG. 9 is a disassembled perspective view of a photoelectric device according to another embodiment of the present invention;

FIG. 10 is a cross-sectional view of the photoelectric device cut along the line X-X of FIG. 9; and

FIG. 11 is an expanded view of a portion of the photoelectric device of the embodiment shown in FIG. 10.

### DETAILED DESCRIPTION

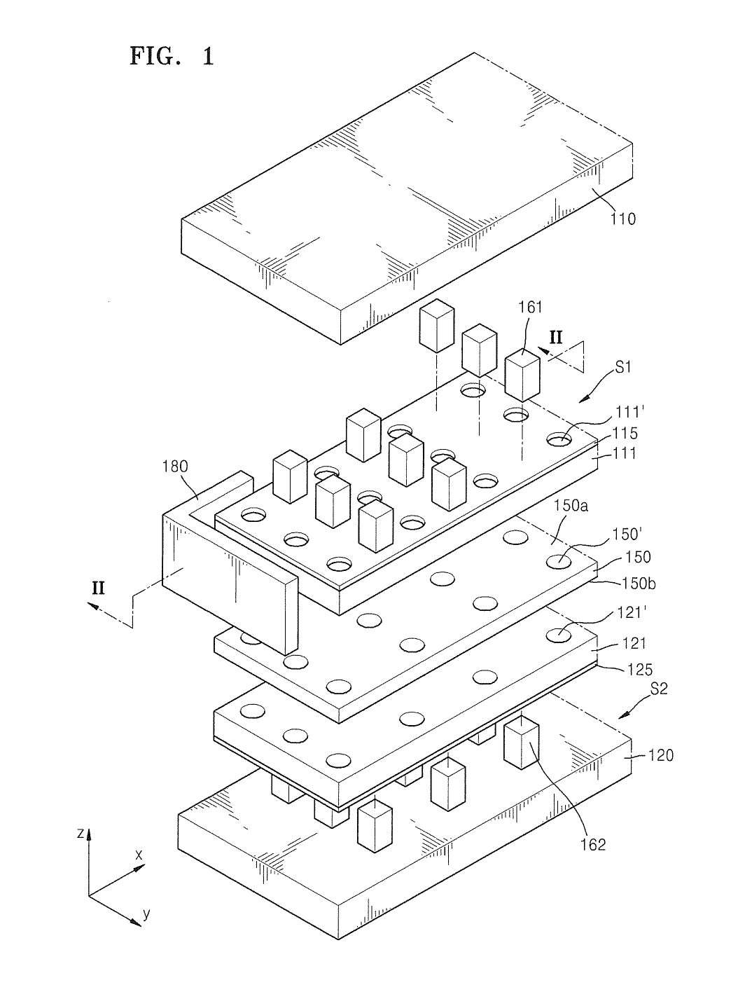

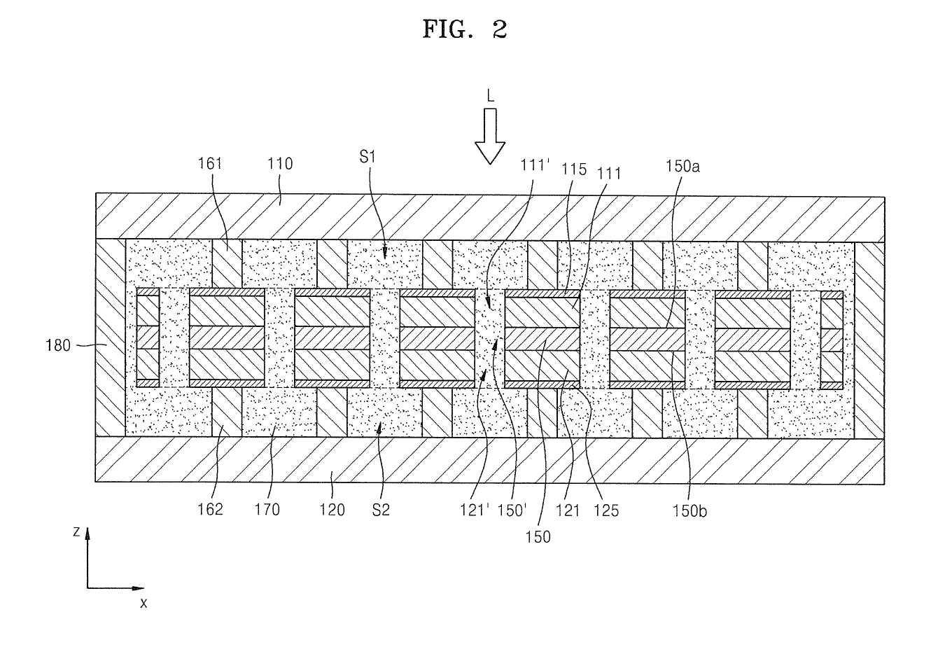

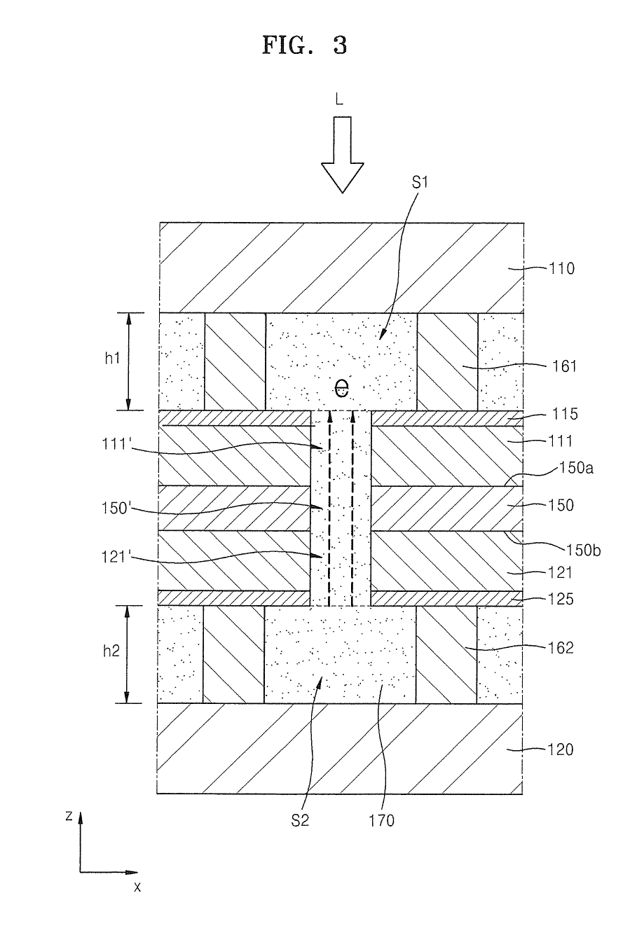

FIG. 1 is a disassembled perspective view of a photoelectric device according to an embodiment of the present invention. FIG. 2 is a cross-sectional view of the photoelectric device of the embodiment shown in FIG. 1 cut along the line II-II. FIG. 3 is an expanded view of a portion of the photoelectric device of the embodiment shown in FIG. 2.

Referring to FIGS. 1, 2, and 3, the photoelectric device includes: first and second substrates 110 and 120; a separator 150 between the first and second substrates 110 and 120 and including a plurality of openings 150′ formed so that first and second surfaces 150a and 150b are fluidally coupled to each to other; and first and second electrodes 111 and 121. In addition, a plurality of openings 111′ and 121′ that are fluidally coupled to the openings 150′ of the separator 150 may be formed in the first and second electrodes 111 and 121.

The first substrate 110 may be a light-receiving surface for receiving incident light, and may be formed of a highly light-transmissive material. For example, the first substrate 110 may be formed of a glass substrate or a resin substrate. A resin substrate usually has flexibility, and is thus suitable for uses where flexibility is desired.

The second substrate 120 is not particularly limited as long as it may accommodate an electrolyte 170, and may be formed of, for example, a glass substrate or a resin substrate. The second substrate 120 may face the first substrate 110 while having the separator 150 therebetween. For example, the second substrate 120 may be coupled to the first substrate 110 using a sealing member 180, which may be located along edges of the first and second substrates 110 and 120, wherein the sealing member 180 surrounds the electrolyte 170 filled between the first and second substrates 110 and 120 to encapsulate the photoelectric device, thereby protecting the photoelectric device from external environments.

As illustrated in FIGS. 2 and 3, the electrolyte 170 is filled between the first and second substrates 110 and 120, which may directly contact the electrolyte 170. Electrodes located at two ends form a current path of the photoelectric device, that is, first and second electrodes 111 and 121 are formed on the separator 150, but are not formed on the first and second substrate 110 and 120. The first and second substrates 110 and 120 excluding the above-described electrode structure may directly contact the electrolyte 170.

The separator 150 physically separates the first and second electrodes 111 and 121, which have opposite polarities, and electrically insulates the first and second electrodes 111 and 121 from each other, thereby preventing or reducing the likelihood of a short circuit due to contact between the first and second electrodes 111 and 121. The separator 150 allows transportation of electrons (e) (see FIG. 3) according to an electrical field between the first and second electrodes 111 and 121, and allows transmission of the electrolyte 170, through which electrons (e) are transferred, and/or allows transmission of iodine ions in the electrolyte 170.

The separator 150 may be formed of an electrically insulating material, and may include a plurality of openings 150′ to allow transmission of the electrolyte 170 or transmission of ions in the electrolyte 170. The first and second surfaces 150a and 150b of the separator 150 are fluidally coupled to each other via the openings 150′. What is meant by “the first and second surfaces 150a and 150b of the separator 150 being fluidally coupled to each other” is that the electrolyte 170, through which electrons (e) or ions in the electrolyte (e.g., electrolyte 170) are transferred, enables the electrons (e) or ions to pass through the separator 150, and that a current path may be formed through the separator 150 between the first electrode 111 and the second electrode 121.

The separator 150 may be formed of a material that has electrical insulation properties, that has little reactivity with respect to the electrolyte 170 in a high-temperature operating environment (e.g., reaching 85 degrees), and that has a stable chemical stability with respect to the electrolyte 170. For example, the separator 150 may be formed of a non-conductive resin material such as polytetrafluoroethylene (e.g., TEFLON®, which is a registered trademark of E. I. du Pont de Nemours and Company, Wilmington Del.), or a vinyl resin.

The openings 150′ of the separator 150 may be formed by processing a planar raw material by perforation, such as by punching, stamping, or molding of a resin material. For example, the separator 150 may be formed of a non-conductive resin material, and a plurality of openings 150′ may be formed by molding a non-conductive resin material.

As long as the openings 150′ of the separator 150 are fluidally coupled, the forms of the openings 150′ of the present embodiment are not limited. As illustrated in FIG. 1, the openings 150′ may be patterned in the separator 150. For example, the openings 150′ may be formed by patterning generally at uniform positions (e.g., a generally uniform pattern), and as illustrated in FIG. 1, the openings 150′ may be arranged in matrix patterns along first and second directions, such as a row direction (x-direction) and a column direction (y-direction).

When forming patterns of the openings 150′, the openings 150′ may be distributed over substantially the entire surface area of the separator 150 (e.g., the first and second surfaces 150a and 150b) with a uniform density so that the electrolyte 170, through which electrons (e) are transported, may be uniformly transmitted. In an area with a low degree of transmission of the electrolyte 170, a path resistance of electron transportation increases, and thus, photoelectric efficiency is decreased. Accordingly, the openings 150′ may be distributed over the entire area of the separator 150 at a uniform density.

The forms of the openings 150′ may be variously formed in consideration of a flow resistance of the electrolyte 170, of workability in regard to perforation, and of mechanical intensity of the separator 150, and as illustrated in FIG. 1, the openings 150′ may have an approximately circular shape, or a polygonal shape, such as a square.

The first and second electrodes 111 and 121 having opposite polarities are arranged on the first and second surfaces 150a and 150b of the separator 150, respectively. The first and second electrodes 111 and 121 may face each other with the separator 150 therebetween, and may have planar shapes over substantially the entire surface areas of the first and second surfaces 150a and 150b of the separator 150.

The first electrode 111 may be formed as a negative electrode of the photoelectric device, for example, which withdraws light-generated carriers such as electrons. The second electrode 121 may be formed as an electrode having an opposite polarity to that of the first electrode 111, for example, as a positive electrode, and may accommodate, for example, a flow of electrons that have passed through an external circuit (not shown) and may supply the same to the first electrode 111.

The first and second electrodes 111 and 121 may be formed of a metal having excellent electric conductivity, having little reactivity with respect to the electrolyte 170 in a high-temperature operating environment (e.g., reaching about 85 degrees), and/or being chemically stable with respect to the electrolyte 170 (e.g., titanium). For example, the first and second electrodes 111 and 121 may be a thin film plate covering substantially the entire surface area of the first and second surfaces 150a and 150b, such as a titanium thin film plate.

A light-absorbing layer 115 may be formed on the first electrode 111, may be electrically coupled to the first electrode 111, and may form a conductive contact with the first electrode 111. The light-absorbing layer 115 may absorb light (L) incident through the first substrate 110 to generate light carriers such as, for example, electrons. The light-absorbing layer 115 may be formed on a surface of the first electrode 111 facing the first substrate 110 so as to absorb as much light (L) as possible.

For example, the light-absorbing layer 115 may include a semiconductor layer to which a photosensitive dye is adsorbed. For example, the semiconductor layer may be formed of an oxide of a metal such as Cd, Zn, In, Pb, Mo, W, Sb, Ti, Ag, Mn, Sn, Zr, Sr, Ga, Si, or Cr.

For example, the photosensitive dye may be formed of molecules that absorb light in a visible ray band and cause fast electron transportation from a light-excited state to a semiconductor layer. For example, the photosensitive dye may be a ruthenium-based photosensitive dye.

A catalyst layer 125 may be formed on the second electrode 121, may be electrically coupled to the second electrode 121, and may form a conductive contact with the second electrode 121. For example, the catalyst layer 125 may function as a reduction catalyst with respect to the electrolyte 170, and may function as a reduction catalyst for receiving electrons provided via the second electrode 121 and for reducing the electrolyte 170, and may ultimately reduce the light-absorbing layer 115, which is oxidized according to withdrawal of light-generated electrons, again. For example, the catalyst layer 125 may be formed on a surface of the second electrode 121 facing the second substrate 120 to form a broad contact surface with the electrolyte 170.

The catalyst layer 125 may be formed of a material having a catalyzed reduction function for providing electrons to the electrolyte 170, and may be formed of, for example, a metal such as platinum (Pt), gold (Ag), silver (Au), copper (Cu), aluminum (Al), a metal oxide such as a tin oxide, and/or a carbonaceous material such as graphite.

In order to allow transmission of the electrolyte 170, a plurality of openings 111′ and 121′ may be formed in the first and second electrodes 111 and 121, and the openings 111′ and 121′ of the first and second electrodes 111 and 121 may be fluidally coupled to the openings 150′ of the separator 150, thereby forming a path of the electrolyte 170 through which electrons are transported.

Referring to FIG. 1, a plurality of openings 111′ may be formed in the first electrode 111 and the light-absorbing layer 115 formed on the first surface 150a of the separator 150 to allow transmission of the electrolyte 170. For example, the openings 111′ of the first electrode 111 and the light-absorbing layer 115 may be aligned. While the openings 111′ of the first electrode 111 and the light-absorbing layer 115 are denoted by the same reference numeral, this is for convenience of understanding, and the openings 111′ of the first electrodes 111 and the light-absorbing layer 115 are not necessarily aligned, according to various embodiments of the present invention.

Similarly, a plurality of openings 121′ may be formed in the second electrode 121 and the catalyst layer 125 formed on the second surface 150b of the separator 150 to allow transmission of the electrode 170. For example, the openings 121′ of the first electrode 121 and the catalyst layer 125 may be aligned. While the openings 121′ of the first electrode 121 and the catalyst layer 125 are denoted by the same reference numeral, this is for convenience of understanding, and the openings 121′ of the first electrodes 121 and the catalyst layer 125 are not necessarily aligned according to various embodiments of the present invention.

The openings 111′ and 121′ of the first and second electrodes 111 and 121 may form a path of the electrolyte 170 coupled to the openings 150′ of the separator 150. By forming a path of the electrode layer 170 that is fluidally coupled from the catalyst layer 125 to the light-absorbing layer 115 in a thickness direction of the separator 150, a path for reduction electrons may be formed from the catalyst layer 125 to the light-absorbing layer 115 through the medium of the electrolyte 170.

According to the embodiment of the invention shown in FIG. 1, the openings 150′ of the separator 150 and the openings 111′ and 121′ of the first and second electrodes 111 and 121 are aligned with each other, and are continuously extended in a thickness direction, although the present invention is not limited thereto. For example, the openings 150′ of the separator 150 and the openings 111′ and 121′ of the first and second electrodes 111 and 121 may be offset from each other as long as they are fluidally coupled to each other to form a path of the electrolyte 170.

A first spacer 161 is located between the first substrate 110 and the separator 150, and may thereby form a first accommodation space S1 between the first substrate 110 and the separator 150. Also, a second spacer 162 is located between the second substrate 120 and the separator 150, and may thereby form a second accommodation space S2 between the second substrate 120 and the separator 150. The first and second accommodation spaces S1 and S2 are fluidally coupled to each other via the openings 111′, 150′, and 121′ of the separator 150 and the first and second electrodes 111 and 121.

The first and second accommodation spaces S1 and S2 and the openings 111′, 150′, and 121′ coupling the spaces S1 and S2 are filled with the electrolyte 170, and a current path between the first electrode 111 (or the light-absorbing layer 115) in the first accommodation space S1 and the second electrode 121 (or the catalyst layer 125) in the second accommodation space S2 may be formed via the electrolyte 170.

Referring to FIG. 3, heights h1 and h2 of the first and second spacers 161 and 162 correspond to a volume of the first accommodation space S1 between the first substrate 110 and the separator 150, and to a volume of the second accommodation space S2 between the second substrate 120 and the separator 150, respectively. For example, by adjusting the heights h1 and h2 of the first and second spacers 161 and 162, volumes of the first and second accommodation spaces S1 and S2 may be controlled (e.g., changed or adjusted), and the amount of the electrolyte 170 stored in the first and second accommodation spaces S1 and S2 may be increased or decreased. According to the current embodiment, the heights h1 and h2 of the first and second spacers 161 and 162 may be approximately the same, but the present invention is not limited thereto.

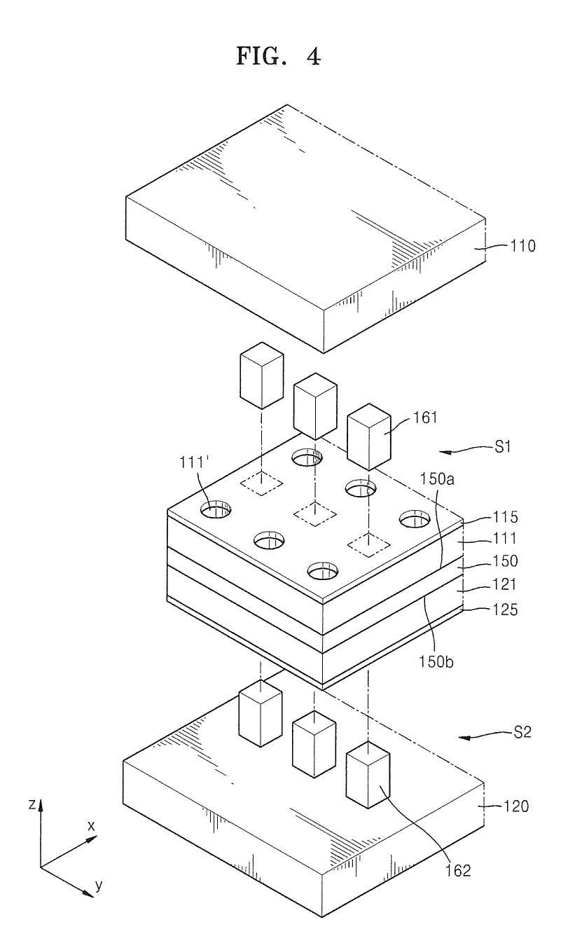

FIG. 4 is a disassembled perspective view of a portion of the photoelectric device of FIG. 1. Referring to FIG. 4, the separator 150 between the first and second substrates 110 and 120 is spaced from the first and second substrate 110 and 120. The separator 150 may be supported by the first and second spacers 161 and 162 via different surfaces, respectively. That is, the first and second surfaces 150a and 150b are respectively supported by the first and second spacers 161 and 162. To firmly fix the separator 150 and to maintain the first and second accommodation spaces S1 and S2 at uniform intervals, a plurality of the first and second spacers 161 and 162 may be included. For example, the first and second spacers 161 and 162 may face each other by interposing the separator 150 therebetween.

A plurality of first spacers 161 may be located on different positions between the first substrate 110 and the light-absorbing layer 115, and a plurality of second spacers 162 may be located on different positions between the second substrate 120 and the catalyst layer 125.

The arrangement, number, and shape of the first and second spacers 161 and 162 are not as illustrated in FIG. 4 but may vary as long as they respectively form the first and second accommodation spaces S1 and S2 between the first and second substrates 110 and 120 and the separator 150. For example, referring to FIG. 4, the first and second spacers 161 and 162 have column forms that are individually isolated.

Alternatively, the first and second spacers 161 and 162 may be, for example striped patterned spacers extended in a direction (e.g., a predetermined direction), or sheet-type spacers in a mesh pattern.

The first spacer 161 may be formed between the first substrate 110 and the light-absorbing layer 115. When the first spacer 161 is formed of a material having a high light transitivity, light loss of the light absorption layer 115 may be reduced, and thus, the first spacer 161 may be formed of glass frit or a transparent resin material.

The first and second spacers 161 and 162 may be formed of a material that may adhere to (and between) the corresponding first and second substrates 110 and 120 and the separator 150 according to heat curing, laser irradiation, or the like; for example, the first and second spacers 161 and 162 may be formed of a glass frit, an organic resin, or a hot melt resin.

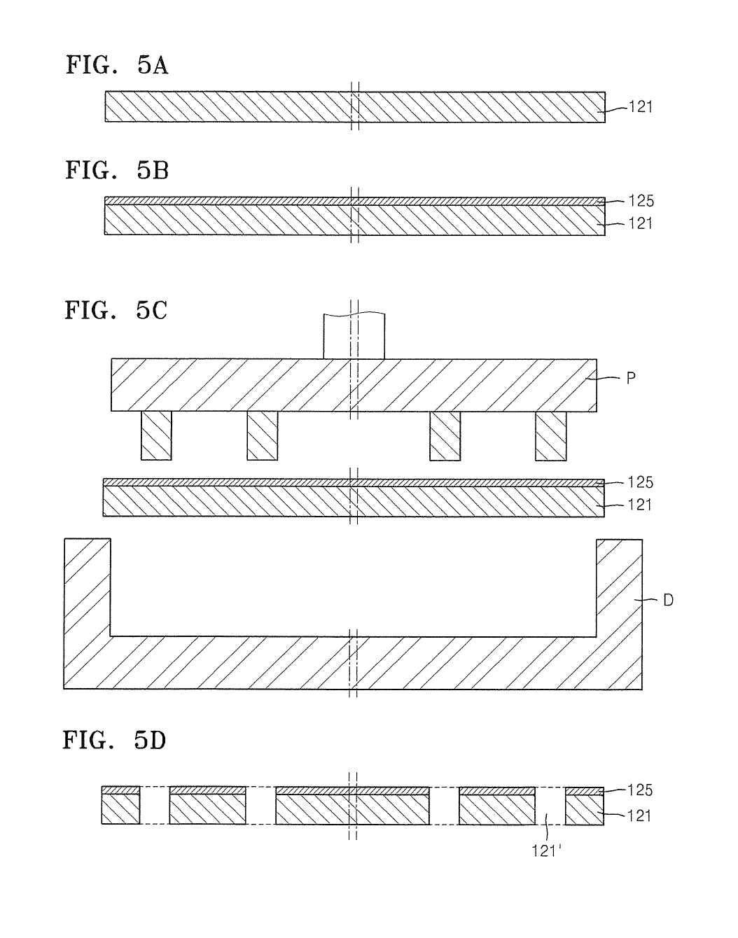

FIGS. 5A through 5D are views for explaining formation of the openings 121′ of the second electrode 121 according to an embodiment of the present invention. As illustrated in FIGS. 5A and 5B, the catalyst layer 125 is stacked on the second electrode 121 to form a raw material substrate. For example, a layer forming process, such as sputtering or printing, may be applied to the second electrode 121 to form the catalyst layer 125.

Next, as illustrated in FIGS. 5C and 5D, the raw material substrate is perforated to form a plurality of openings 121′. For perforation of the raw material substrate, punching or stamping may be applied.

For example, the raw material substrate may be placed on a worktable (D) and pressed using a press (P) to perforate the catalyst layer 125 and the second electrode 121, and the openings 121′ of the catalyst layer 125 and the second electrode 121 may be aligned.

Meanwhile, similar to FIGS. 5A through 5D, the same operations may form the openings 111′ of the first electrode 111. That is, the light-absorbing layer 115 may be stacked on the first electrode 111 to form a raw material substrate, and the raw material substrate may perforate the light-absorbing layer 115 and the first electrode 111, and the openings 111′ of the light-absorbing layer 115 and the first electrode 111 may be aligned.

However, the embodiments of the present invention are not limited thereto, and, for example, the first electrode 111 may be perforated to form a plurality of openings 111′, and then the light-absorbing layer 115 may be patterned to correspond to patterns of the openings 111′ of the first electrode 111.

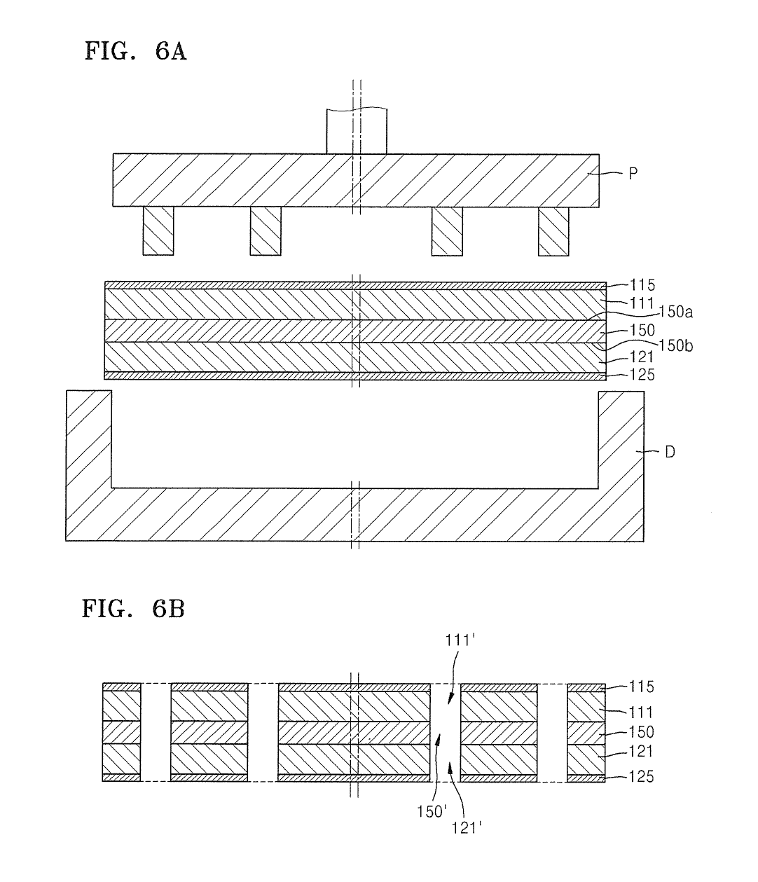

FIGS. 6A and 6B are views for explaining formation of the openings 111′, 150′, and 121′ of the separator 150 and the first and second electrodes 111 and 121 according to an embodiment of the present invention. Referring to FIGS. 6A and 6B, the first electrode 111 and the light-absorbing layer 115 are stacked on the first surface 150a of the separator 150, and the second electrode 121 and the catalyst layer 125 are stacked on the second surface 150b of the separator 150, thereby forming a raw material substrate. Then, the raw material substrate may be perforated. For perforation of the raw material substrate, punching or stamping may be applied.

For example, the raw material substrate may be placed on a worktable (D) and pressed using a press (P) to thereby perforate the first and second electrodes 111 and 121 and the separator 150, and the openings 111′, 150′, and 121′ of the first and second electrodes 111 and 121 and the separator 150 may be aligned.

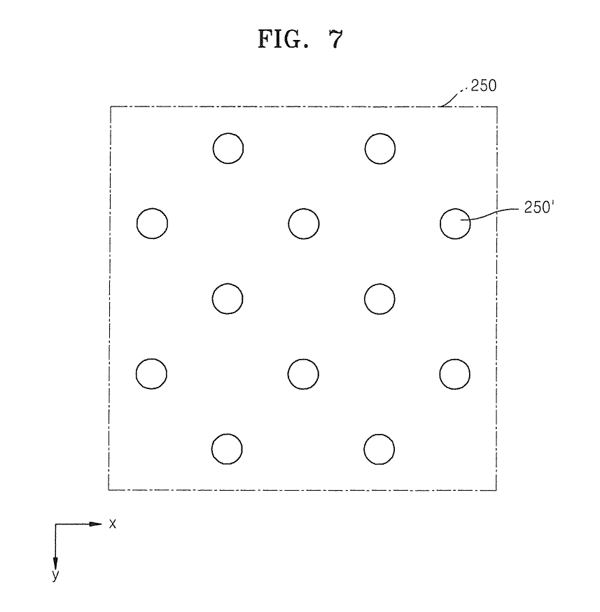

FIG. 7 is a plan view of a separator 250 according to another embodiment of the present invention. Referring to FIG. 7, a plurality of openings 250′ are arranged in the separator 250 in alternate patterns; for example, a row of openings 250′ may be arranged in alternating positions with respect to an adjacent row of openings 250′, or a column of openings 250′ might not be aligned with an adjacent column of openings 250′. According to this pattern of the openings 250′, transmission of the electrolyte 170 may be uniformly conducted over the entire area of the separator 250. Alternatively, the openings 250′ of the separator 250 may be arranged, for example, at irregular positions instead of at regular positions in regular patterns.

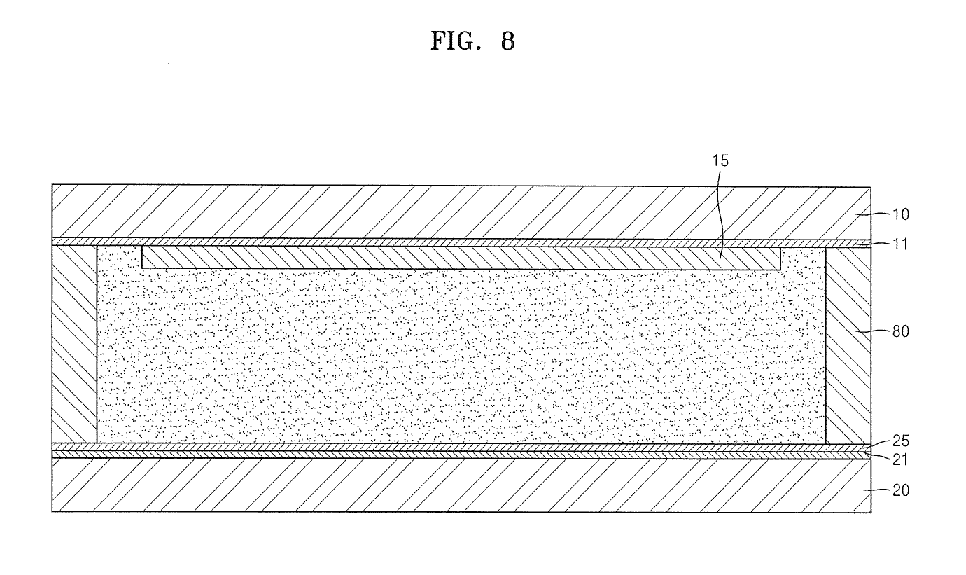

FIG. 8 is a cross-sectional view of a photoelectric device according to a comparative example. Referring to FIG. 8, the photoelectric device includes first and second substrate 10 and 20, and first and second electrodes 11 and 21 respectively formed on the first and second substrate 10 and 20. The photoelectric device includes a light-absorbing layer 15 formed on the first electrode 11, and a catalyst layer 25 formed on the second electrode 21.

Light that has transmitted through the first electrode 11 is absorbed by the light-absorbing layer 15, and electrons are generated through excitation of the light-absorbing layer 15. The first electrode 11 is formed of a material having electrical conductivity and also optical transparency so as to allow light transmission. For example, the first electrode 11 may be formed of a transparent conducting oxide (TCO) such as indium tin oxide (ITO), fluorine tin oxide (FTO), or antimony tin oxide (ATO). To form a transparent conductive layer, expensive materials and special layer forming processes are required, and this increases the manufacturing costs of the photoelectric device. In addition, due to the characteristics of the material of the transparent conductive layer, the transparent conductive layer has low electrical conductivity, which increases electrical resistance of a photocurrent.

Meanwhile, the second electrode 21 is formed on the second substrate 20, and in consideration of adhering characteristics with respect to the second substrate 20, which is a glass substrate, the second electrode 21 is also formed of a transparent conductive layer. As a result, according to the comparative example, transparent conductive layers are used to a wide extent as the first and second electrodes 11 and 21, and thus, the manufacturing costs are increased, and due to the decreased conductive characteristics compared to metals, resistance loss is generated.

According to the embodiment of FIG. 1, the light-absorbing layer 115 is formed in front of the first electrode 111 along a direction of light incidence, and thus, the first electrode 111 may be formed of, for example, an opaque metal. That is, as the first electrode 111 and the light-absorbing layer 115 are sequentially formed on the separator 150, the first electrode 111 may be excluded from a path of incidence of the light-absorbing layer 115, and the first electrode 111 may be formed of an opaque metal. By forming the first electrode 111 using a metal instead of a transparent conductive layer, manufacturing costs of the photoelectric device may be reduced, and loss due to electrical resistance may also be reduced.

The second electrode 121 is formed on the second surface 150b of the separator 150, and thus, there is no need to consider adhering characteristics of the second electrode 121 with the second substrate 120. Accordingly, the second electrode 121 may be formed of a metal having excellent electrical conductivity. By forming the second electrode 121 using a metal instead of a transparent conductive layer, manufacturing costs of the photoelectric device may be reduced, and loss due to electrical resistance may also be reduced.

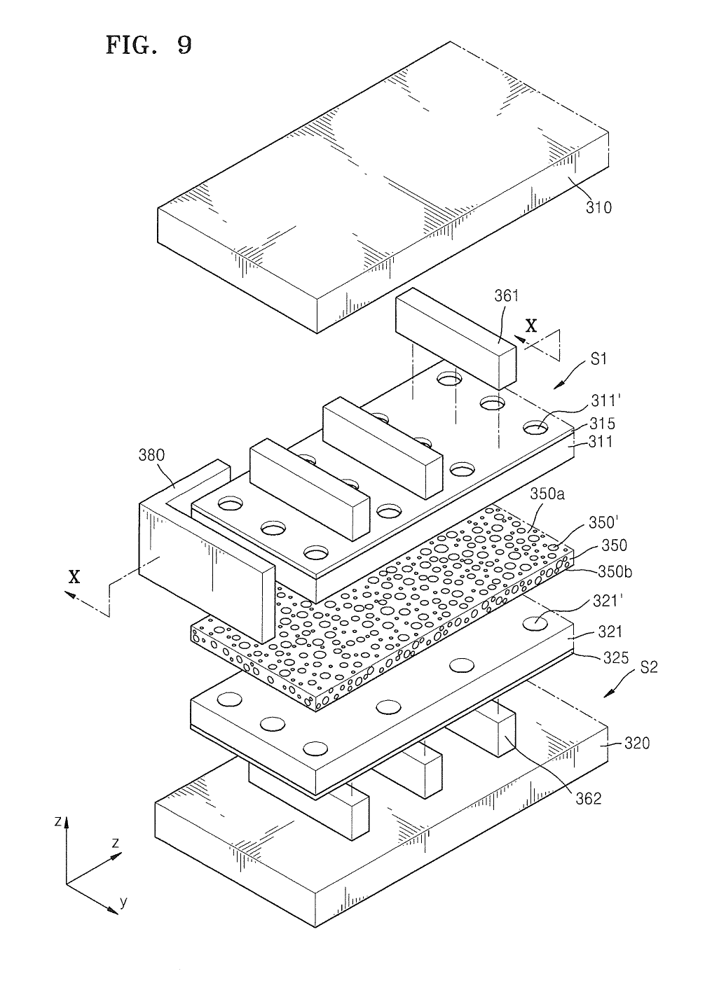

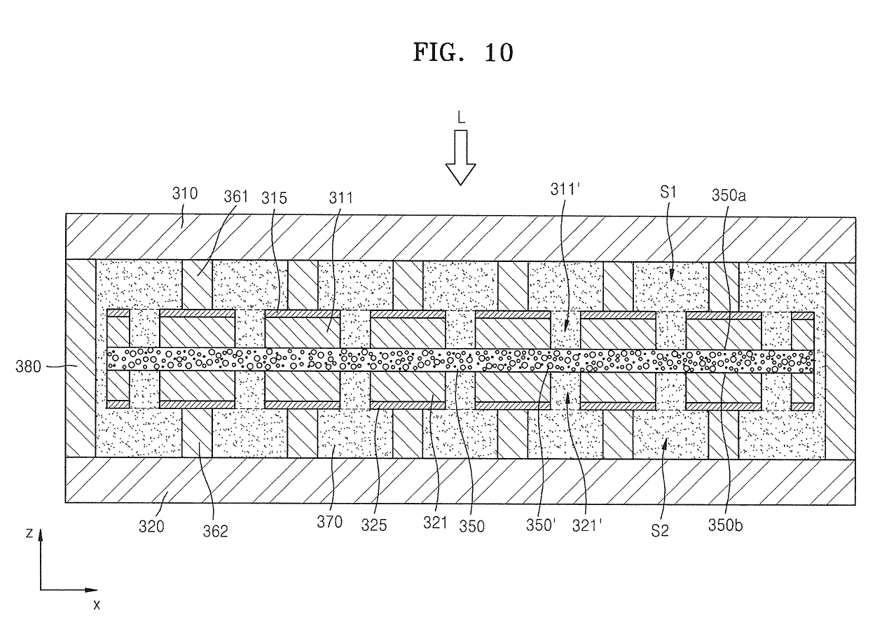

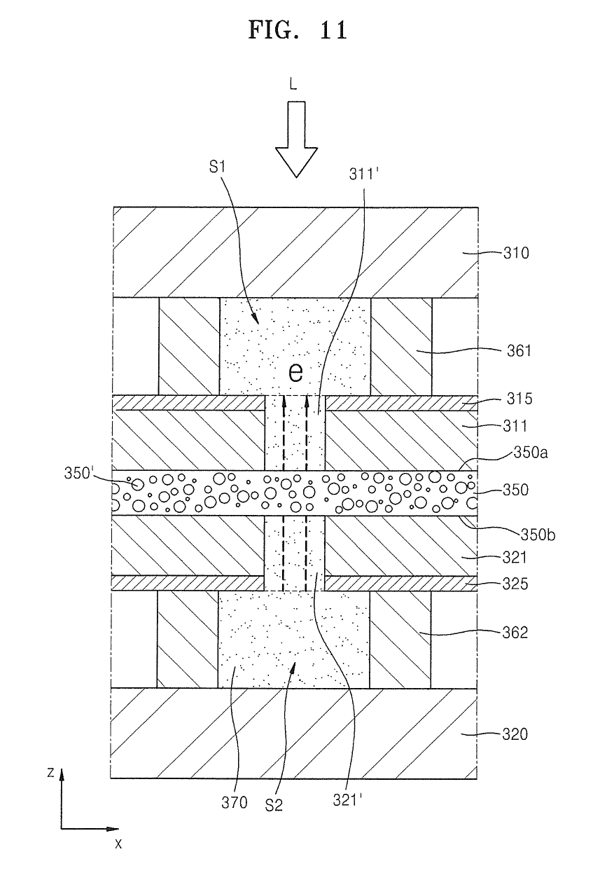

FIG. 9 is a disassembled perspective view of a photoelectric device according to another embodiment of the present invention. FIG. 10 is a cross-sectional view of the photoelectric device of the embodiment shown in FIG. 9 and cut along the line X-X of FIG. 9. FIG. 11 is an expanded view of a portion of the photoelectric device of the embodiment shown in FIG. 10.

Referring to FIGS. 9 through 11, the photoelectric device includes first and second substrates 310 and 320 facing each other, and a separator 350 between the first and second substrates 310 and 320 and including a plurality of openings 350′ that are formed so that opposite first and second surfaces 350a and 350b of the separator 350 are fluidally coupled. In addition, the photoelectric device includes first and second electrodes 311 and 321 that are formed on the first and second surfaces 350a and 350b of the separator 350, respectively.

The separator 350 physically separates the first and second electrodes 311 and 321 of different polarities, and electrically insulates the first and second electrodes 311 and 321 from each other, thereby preventing or reducing the likelihood of a short circuit due to contact between the first and second electrodes 311 and 321. The separator 350 allows transportation of electrons (e) according to an electrical field between the first and second electrodes 311 and 321, and, for example, transmission of the electrolyte 370, through which electrons (e) are transferred.

The separator 350 may be formed of an electrical insulation material, and may have a porous structure in which a plurality of openings 350′ are formed so that the electrolyte 370 may transmit therethrough. For example, the separator 350 may be formed of a porous inorganic material.

When the separator 350 has a porous structure, a plurality of openings 350′ arranged on a two-dimensional plane, or a plurality of openings 350′ arranged three-dimensionally, may be included. For example, the separator 350 may include a silicon (Si) oxide or a zirconium (Zr) oxide; for example, the separator 350 may have a structure in which a plurality of oxide particles are adhered to one another while having pores interposed therebetween, or the separator 350 may be an inorganic thin layer that is formed on a sponge-shaped carrier substrate (not shown) including a plurality of pores. The pores between the plurality of oxide particles or the pores of the carrier substrate correspond to the openings 350′ that allow transmission of the electrolyte 370. Also, the separator 350 may be formed as a membrane in which a plurality of pores are arranged two-dimensionally, and the plurality of pores may correspond to the openings 350′ that allow transmission of the electrolyte 370.

When the separator 350 has a porous structure, this porous structure includes openings 350′ of both relatively fine scales and coarse scales. For example, the porous structure of the separator 350 may be formed by performing a mechanical forming operation, such as punching or stamping a planar raw material, or by performing various porous processes, such as sintering of micro-scale particles.

The first and second electrodes 311 and 321 of opposite polarities are formed on the first and second surfaces 350a and 350b of the separator 350, respectively. The first and second electrodes 311 and 321 may be formed of a metal having excellent electrical conductivity, and may be formed as a metal thin plate over the entire surface areas on the first and second surfaces 350a and 350b. For example, the first and second electrodes 311 and 321 may include titanium thin plates.

According to the present embodiment, as the first and second electrodes 311 and 321 are formed of a metal, costs for transparent conductive layers may be reduced, and loss from resistance due to the first and second electrodes 311 and 321 may be reduced. In detail, by placing a light-absorbing layer 315 in front of the first electrode 311 in a direction of incidence of light (L), optical transparency of the first electrode 311 is not to be considered. Accordingly, the first electrode 311 may be formed of a metal instead of a transparent conductive layer, thereby reducing loss caused by resistance.

The light-absorbing layer 315 may be formed on the first electrode 311. The light-absorbing layer 315 may be formed on a surface of the first electrode 311 facing the first substrate 310 so that as much light (L) as possible may be absorbed by the light-absorbing layer 315. A catalyst layer 325 may be formed on the second electrode 320. To form a broad contact surface area with the electrolyte 370, the catalyst layer 325 may be formed on a surface of the second electrode 321 facing the second substrate 320.

A plurality of openings 311′ and 321′ may be formed in the first and second electrodes 311 and 321 to allow transmission of the electrolyte 370, and the openings 311′ and 321′ of the first and second electrodes 311 and 321 may be fluidally coupled to the openings 350′ of the separator 350 to form a path of the electrolyte 370, through which electrons (e) are transported. By forming a path of the electrolyte 370 that is fluidally coupled from the catalyst layer 325 to the light-absorbing layer 315 in a thickness direction of the separator 350, transportation of electrons (e) may be conducted through the electrolyte 370.

A first spacer 361 is located between the first substrate 310 and the separator 350, and may enable a first accommodation space S1 between the first substrate 310 and the separator 350. Also, a second spacer 362 is located between the second substrate 320 and the separator 350, and may enable a second accommodation space S2 between the second substrate 320 and the separator 350. The first and second accommodation spaces S1 and S2 are fluidally coupled to each other via the openings 311′, 350′, and 321′ of the separator 350 and the first and second electrodes 311 and 321.

The first and second spacers 361 and 362 may respectively support the first and second surfaces 350a and 350b of the separator 350, and may fix the separator 350 in a position separated from the first and second substrates 310 and 320. To firmly fix the separator 350, and also to maintain the first and second accommodation spaces S1 and S2 at uniform intervals, a plurality of the first and second spacers 361 and 362 may be included.

As illustrated in FIG. 9, the first and second spacers 361 and 362 may be striped patterned spacers extended in a direction (e.g., a predetermined direction or a y-direction). For example, the first spacer 361 may extend between adjacent rows of openings 311′ in the first electrode 311 (e.g., a predetermined direction or the y-direction). Also, the second spacer 362 may extend between adjacent rows of openings 321′ in the second electrode 321 (e.g., a predetermined direction or the y-direction).

A flow path (not shown) having a ruptured form may be formed in the first and second spacers 361 and 362, and flow of the electrolyte 370 may be allowed through the flow path. The structure of the flow path described above is provided in order to increase photoelectric conversion efficiency of predetermined areas due to accumulation of the electrolyte 370.

Meanwhile, a sealing member 380 may be located along edges of the first and second substrates 310 and 320. By coupling the first and second substrates 310 and 320 by interposing the sealing member 380 therebetween, the first and second accommodation spaces S1 and S2 accommodating the electrolyte 370 may be encapsulated.

It should be understood that the described exemplary embodiments of the present invention should be considered in a descriptive sense only and not for purposes of limitation. Descriptions of features or aspects within each embodiment should typically be considered as available for other similar features or aspects in other embodiments. While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and their equivalents.

Description of Some of the Reference Characters

| | |
|---|---|
| 110, 310: first substrate | 111, 311: first electrode |
| 111′,311′: opening of first electrode and | |
| light-absorbing layer | |
| 121′,321′: opening of second electrode | |
| and catalyst layer | |
| 115, 315: light-absorbing layer | 120, 320: second substrate |
| 121, 321: second electrode | 150, 250, 350 : separator |
| 150′, 250′, 350′: opening of the separator | 125, 325: catalyst layer |
| 150a, 350a : first surface of separator | |
| 150b, 350b : second surface of separator | |
| 161, 361: first spacer | 162, 362: second spacer |
| 170, 370: electrolyte | 180, 380: sealing member |
| S1: first accommodation space | S2: second accommodation space |
| h1: height of first spacer | h2: height of second spacer |
| e: electron | |

What is claimed is:

1. A photoelectric device comprising:
first and second substrates facing each other;
a separator between the first and second substrates and having a plurality of openings such that opposite first and second surfaces of the separator are fluidly connected to each other; and
first and second electrodes on the first and second surfaces of the separator, respectively,
wherein the first and second electrodes are fluidly connected to the openings of the separator.

2. The photoelectric device of claim 1, wherein the first and second electrodes each have openings.

3. The photoelectric device of claim 2, wherein the openings of the first and second electrodes are aligned with the openings of the separator.

4. The photoelectric device of claim 1, wherein the first and second electrodes each comprise a metal plate.

5. The photoelectric device of claim 4, wherein the first and second electrodes each comprise titanium.

6. The photoelectric device of claim 1, further comprising:
a light-absorbing layer on the first electrode; and
a catalyst layer on the second electrode.

7. The photoelectric device of claim 6, wherein the light-absorbing layer is on a surface of the first electrode facing the first substrate, and
wherein the catalyst layer is on a surface of the second electrode facing the second substrate.

8. The photoelectric device of claim 6, wherein the first and second electrodes, the light-absorbing layer, and the catalyst layer each have openings that are fluidly connected to the openings of the separator.

9. The photoelectric device of claim 1, wherein the openings of the separator have a generally regular pattern.

10. The photoelectric device of claim 1, wherein at least a portion of the separator is porous.

11. The photoelectric device of claim 1, further comprising an electrolyte between and directly contacting the first and second substrates.

12. The photoelectric device of claim 1, wherein the separator comprises an insulating material to electrically insulate the first and second electrodes from each other.

13. The photoelectric device of claim 12, wherein the separator comprises at least one of a non-conductive resin material or a porous inorganic material.

14. The photoelectric device of claim 13, wherein the separator comprises at least one of polytetrafluoroethylene, a vinyl resin, a silicon (Si) oxide, or a zirconium (Zr) oxide.

15. The photoelectric device of claim 1, further comprising:
a first spacer between the first substrate and the separator; and
a second spacer between the second substrate and the separator.

16. The photoelectric device of claim 15, having first and second accommodation spaces that are proximate the first and second spacers, respectively, and that are fluidly connected to each other via the openings in the separator.

17. The photoelectric device of claim 16, further comprising:
a plurality of first spacers on different portions at a first side of the separator; and
a plurality of second spacers on different portions at a second side of the separator.

18. The photoelectric device of claim 15, further comprising a plurality of first and second spacers between the separator and the first and second substrates, respectively, wherein the separator is spaced from the first and second substrates.

19. The photoelectric device of claim 15, wherein the first spacer comprises a transparent material, and
wherein the first substrate is configured to receive light.

20. The photoelectric device of claim 1, further comprising a sealing member between the first and second substrates and spaced from the separator.
